(19) United States
(12) Patent Application Publication
(10) Pub. No.: US 2006/0073638 A1
(43) Pub. Date: Apr. 6, 2006

(54) Semiconductor electrical connection structure and method of fabricating the same

(75) Inventor: Shih-Ping HSU, Hsin-chu (TW)

Correspondence Address: Mr. William F. Nixon;SQUIRE SANDERS & DEMPSEY LLP, 14th Floor, 8000 Towers Crescent Drive, Tysons Corner, VA, 22182-2700, US

(73) Assignee: Phoenix Precision Technology Corporation

(21) Appl. No.: 11/022,789

(22) Filed: Dec. 28, 2004

(30) Foreign Application Priority Data
Sep. 1, 2004 (TW) 093126320

(51) Int. Cl. H01L 21/50

(52) U.S. Cl. 438/110

(57) ABSTRACT

A semiconductor electrical connection structure and a method of fabricating the same are provided. A wafer formed with a plurality of gold bumps thereon is divided into a plurality of individual chips. A carrier is prepared, and at least one of the chips is mounted on the carrier via a non-active surface of the chip. An insulating layer is applied on the carrier mounted with the chip, and formed with a plurality of openings using a laser drilling, photo imaging or plasma etching technique to expose the gold bumps via the openings. A conductive layer is formed on the insulating layer and in the openings. A pattered resist layer is applied on the conductive layer to define openings for electroplating. A circuit structure is electroplated in the openings of the resist layer so as to allow the chip to be electrically connected to an external device via the circuit structure.

### FIELD OF THE INVENTION

The present invention relates to semiconductor electrical connection structures and methods of fabricating the same, and more particularly, to a semiconductor electrical connection structure and a fabrication method thereof without using a wire-bonding or flip-chip technique.

### BACKGROUND OF THE INVENTION

Since the IBM Company has introduced a flip-chip packaging technique in early 1960s, as compared with a wire-bonding technique, the flip-chip technology is characterized in electrically connecting a semiconductor chip to a substrate by means of solder bumps instead of gold wires. Such flip-chip technology yields advantages that the packaging density can be increased to reduce the size of package, and electrical performance of the package can be improved as not requiring long metal or gold wires. Therefore, the industry has utilized high-temperature solder for electrically connecting a flip chip to a ceramic substrate by so-called control-collapse chip connection (C4) process for a long time.

In recent years, as high-density, high-speed and low-cost semiconductor packages have become more demanded and electronic products have been gradually made smaller in size, it is commonly adopted to mount a flip chip on a low-cost organic circuit board (e.g. printed circuit board or substrate) and fill a gap between the flip chip and the organic circuit board with epoxy resin using an underfill technique so as to reduce thermal stress generated by mismatch in coefficient of thermal expansion (CTE) between the silicon chip and the organic circuit board.

The current flip-chip technique is to dispose electrode pads on a surface of the chip and corresponding contact pads on the organic circuit board, and properly form solder bumps or other conductively adhesive materials between the chip and the circuit board, wherein the solder bumps or other electrically conductive adhesive materials are bonded to the electrode pads of the chip and the contact pads of the circuit board respectively. As such, the chip is mounted in a face-down manner on the circuit board, and the solder bumps or electrically conductive adhesive materials provide electrical input/output (I/O) connections and mechanical connections between the chip and the circuit board.

FIG. 1 shows a conventional flip-chip package. As shown in FIG. 1, a plurality of metal bumps 11 are formed on electrode pads 12 of a semiconductor chip 13, and a plurality of presolder bumps 14 made of solder materials are formed on contact pads 15 of an organic circuit board 16. Under a reflowing temperature in which the presolder bumps 14 would melt, the presolder bumps 14 are reflow-soldered to the corresponding metal bumps 11 to form solder joints 17. Further, an underfill material 18 can be filled into a gap between the chip 13 and the circuit board 16 so as to reduce thermal stress caused by mismatch in CTE between the chip 13 and the circuit board 16 to be exerted on the solder joints 17.

However, the flip-chip package only incorporates or packages elements or components on a surface of the circuit board, thereby not easy to improve the density of packaged elements or components. Moreover, the semiconductor chip embedded in the package structure is not subject to good heat dissipation, making the package structure be in danger of overheat that would adversely affect the lifetime of the chip.

In addition, during the flip-chip packaging processes, the metal bumps should be formed on the chip, and the corresponding presolder bumps should be provided on the circuit board, such that the metal bumps and the presolder bumps are reflow-soldered together to form electrical connections between the chip and the circuit board, and then the flip-chip underfill process is performed. Such fabrication processes are complicated and require high cost. And the solder bumps after being reflow-soldered become spherical and make a pitch between adjacent bumps not easy to reduce due to the spherical shape thereof. Moreover, during the reflow-soldering process, the solder materials would melt and easily become bridged together, and thus seriously affect the reliability in fabrication. In addition, the solder materials used are Sn/Pb alloys and may cause environmental issues. Alternatively, if employing lead-free processes, the quality stability would however be degraded, and the circuit board may be damaged under a high temperature about 260° C. for performing the lead-free processes.

Moreover, in order to satisfy users' requirements of lighter, size and multiple functions for electronic products, semiconductor chip manufacturers and packaging manufacturers set miniaturization of chips in size as a production and research goal. After the miniaturized chip is fabricated with semiconductor integrated circuits, it needs to be electrically connected to an external device via a carrier so as to realize circuit functions. Thus, the semiconductor packaging processes performed by the packaging manufacturers involve carrier manufacturers. This however causes an interface integration problem and also consumes time and cost.

### SUMMARY OF THE INVENTION

In light of the drawbacks in the prior art, a primary objective of the present invention is to provide a semiconductor electrical connection structure and a method of fabricating the same so as to improve the quality and reliability of electrical connection interface of a semiconductor device.

Another objective of the present invention is to provide a semiconductor electrical connection structure and a method of fabricating the same, which can achieve a fine bump pitch between electrical connection components.

Still another objective of the present invention is to provide a semiconductor electrical connection structure and a method of fabricating the same so as to simplify the fabrication processes and reduce the cost of a semiconductor device.

A further objective of the present invention is to provide a semiconductor electrical connection structure and a method of fabricating the same so as to improve the assembling intensity and functions of a semiconductor device.

A further objective of the present invention is to provide a semiconductor electrical connection structure and a method of fabricating the same, which do not require the packaging processes and thus reduce the cost.

A further objective of the present invention is to provide a semiconductor electrical connection structure and a method of fabricating the same so as to solve an interface integration problem during fabrication of a semiconductor device.

In order to achieve the above and other objectives, the present invention proposes a method of fabricating a semiconductor electrical connection structure, including the steps of: providing a wafer comprising a plurality of semiconductor chips, wherein a plurality of electrical connection pads are formed on an active surface of each of the chips; forming a plurality of gold bumps on the electrical connection pads respectively; dividing the wafer into the plurality of individual chips each having the gold bumps thereon; mounting at least one of the chips on a carrier via a non-active surface of the chip; forming a dielectric layer on the chip and the carrier, and forming a plurality of openings in the dielectric layer to expose the gold bumps via the openings; forming a conductive layer on the dielectric layer and in the openings, and forming a patterned resist layer on the conductive layer, which covers a portion of the conductive layer and defines openings for electroplating; and electroplating at least one circuit structure in the openings of the resist layer, the circuit structure being electrically connected to the gold bumps. Afterwards, the resist layer and the portion of the conductive layer covered by the resist layer can be removed. In the present invention, the gold bumps formed on the electrical connection pads of the chip are not easily oxidized, and have better utility and reliability as compared with conventional solder bumps comprising non-environmental-friendly materials such as tin and lead and easily causing an electrical bridging effect due to melt of the solder bumps during a reflow-soldering process. Between the gold bumps and the electrical connection pads there can further be formed a UBM (under bump metallurgy) layer. A protection layer is further applied on the active surface of the chip and has a plurality of openings for exposing the electrical connection pads.

By the foregoing method, a semiconductor electrical connection structure according to the present invention is fabricated, including: a carrier; at least one semiconductor chip mounted via its non-active surface on the carrier, wherein an active surface of the chip has a plurality of electrical connection pads thereon, and a plurality of gold bumps are formed on the electrical connection pads respectively; an dielectric layer formed on the carrier mounted with the chip, and having a plurality of openings for exposing the gold bumps; and at least one circuit structure formed on the dielectric layer and electrically connected to the gold bumps. The semiconductor electrical connection structure and the method of fabricating the same according to the present invention firstly form the gold bumps on the electrical connection pads of the semiconductor chip; next, mount the chip having the gold bumps on the carrier; and then form the circuit structure on the carrier, the circuit structure being electrically connected to the chip. This does not require the packaging processes, thereby simplifying the fabrication processes and reducing the cost.

In addition, the semiconductor electrical connection structure and the method of fabricating the same according to the present invention integrate the semiconductor chip having the gold bumps on the carrier, thereby improving the electrical quality, assembling density and functions of the semiconductor electrical connection structure. Moreover, the present invention allows the circuit structure to be directly electrically connected to the gold bumps, such that good electrical connection and reliability as well as structural simplification are achieved.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional flip-chip package;

FIGS. 2A to 2I are cross-sectional views showing procedural steps of a method of fabricating a semiconductor electrical connection structure according to the present invention;

FIG. 2C′ is a cross-sectional view showing a metal layer formed on each gold bump of a semiconductor chip; and

FIGS. 3 and 4 are cross-sectional views showing the semiconductor electrical connection structure according to the present invention further formed with a build-up circuit structure and solder balls thereon.

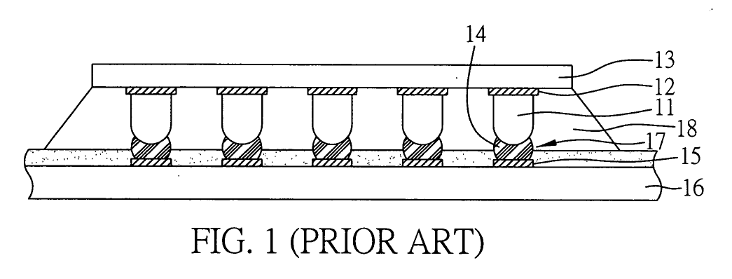

### DETAILED DESCRIPTION OF THE PREFERRED EMBODIMENT

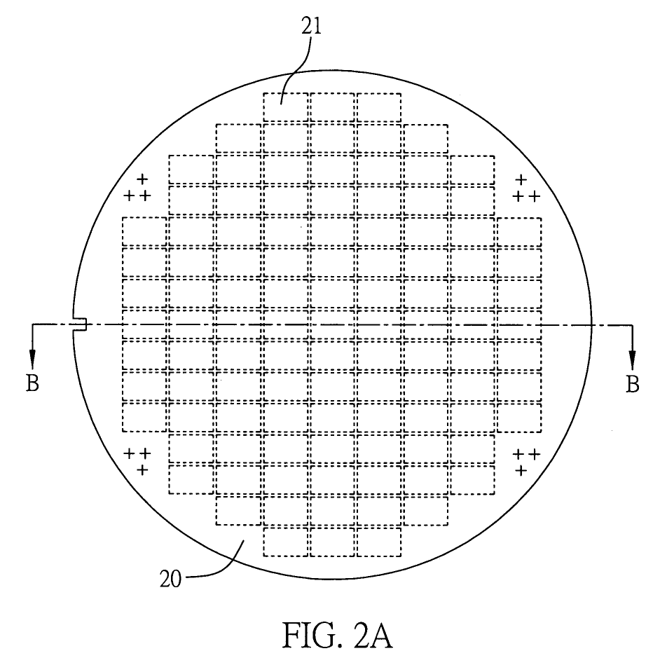

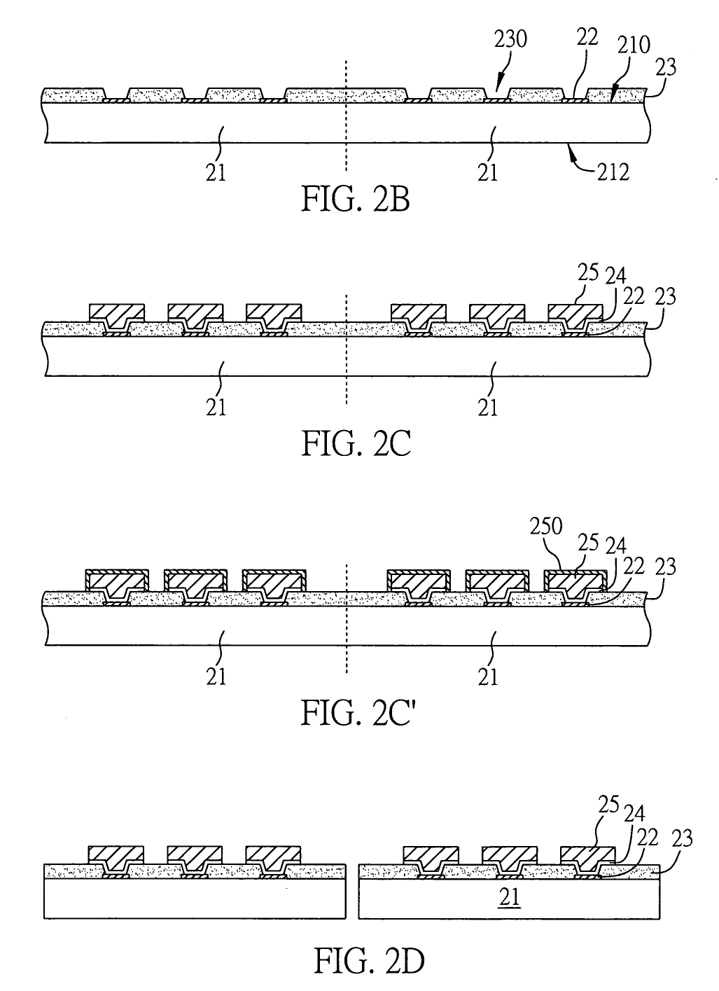

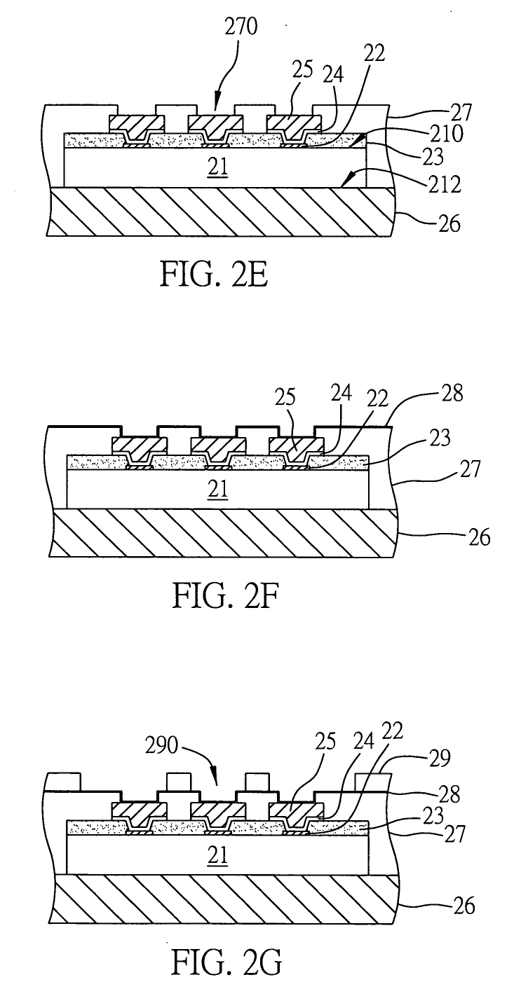

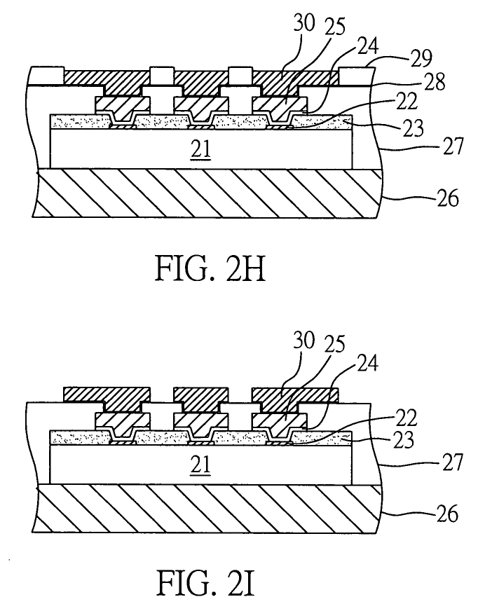

FIGS. 2A to 2I are cross-sectional views showing a method of fabricating a semiconductor electrical connection structure according to the present invention, wherein FIG. 2A is a top view of a semiconductor wafer, and FIGS. 2B to 2I are cross-sectional views showing a method of fabricating a build-up structure on a semiconductor chip according to a preferable embodiment of the present invention. It should be noted that the drawings are simplified schematic diagrams showing basic architecture of the present invention, and thus only show components or elements relevant to the present invention. The components or elements shown in the drawings are not made in real number, shape and size ratio. In practice, the number, shape and size ratio of components or elements can be flexibly arranged as an option of design, and the layout of components or elements would be more complex.

Referring first to FIG. 2A, a wafer 20 is provided comprising a plurality of semiconductor chips 21.

FIG. 2B is a cross-sectional view of two adjacent semiconductor chips 21 taken along line B-B in FIG. 2A. As shown in FIG. 2B, each of the semiconductor chips 21 has an active surface 210 and a non-active surface 212 opposed to the active surface 210. The active surface 210 of each of the chips 21 has a plurality of electrical connection pads 22 thereon, and is further applied with a protection layer 23, the protection layer 23 having a plurality of openings 230 for exposing the electrical connection pads 22.

Referring to FIG. 2C, an under bump metallurgy (UBM) layer 24 is formed on the electrical connection pads 22, side walls of the openings 230 and around the openings 230 on the protection layer 23, such that a gold bump 25 is formed on the UBM layer 24 corresponding to each of the electrical connection pads 22. The UBM layer 24 and the gold bump 25 may be formed by a physical deposition, chemical deposition, sputtering, evaporation, electroless plating or electroplating technique, etc. Moreover, the gold bumps are not easily oxidized, and have better utility and reliability as compared with conventional solder bumps comprising non-environmental-friendly materials such as tin and lead and easily causing an electrical bridging effect due to melt of the solder bumps during a reflow-soldering process. Furthermore, a metal layer 250 such as copper (as shown in FIG. 2C′) can further be formed on a surface of each of the gold bumps 25. The metal layer 250 may be roughened to provide better bondability between the chip 21 and a dielectric layer where the chip 32 is subsequently to be embedded and thus enhance the electrical connection quality between a subsequent circuit structure and the chip.

Referring to FIG. 2D, the wafer 20 is divided into the plurality of individual chips 21 each having the gold bumps 25 thereon. The dicing method of the wafer 20 is conventional and not to be further detailed herein.

Referring to FIG. 2E, at least one of the chips 21 is mounted via its non-active surface 212 on a carrier 26. A dielectric layer 27 is formed on the carrier 26 mounted with the chip 21. A plurality of openings 270 are formed in the dielectric layer 27 to expose top surfaces of the gold bumps 25 via the openings 270. The dielectric layer 27 is applied on the carrier 26 by a printing, spin-coating, coating or attaching and pressing technique, etc. The insulating layer 27 can be made of epoxy resin, polyimide, benzocycle butene (BCB), cyanate ester, Ajinomoto (Japanese company name) build-up film (ABF), bismaleimide triazine (BT), or a mixture of epoxy resin and glass fiber, etc. The openings 270 are formed in the dielectric layer 27 corresponding to the gold bumps 25 by a laser drilling, photoimaging or plasma etching technique, etc. The carrier 26 can be for example a metal plate, insulating plate or circuit board. Besides on a surface of the carrier 26, the chip 21 can also be mounted in a predetermined opening or recess or on a predetermined protrusion of the carrier 26.

Referring to 2F, a conductive layer 28 is formed on the dielectric layer 27 and in the openings 270. The conductive layer 28 primarily serves as a current conducting path for subsequently electroplating a metal material. The conductive layer 28 may be made of a metal material such as copper (Cu), palladium (Pd), chromium (Cr), titanium (Ti) or titanium-wolfram (Ti—W) alloy, etc. Alternatively, the conductive layer 28 can be made of an electrically conductive polymer material such as polyacetylene, polyaniline or organic sulfur polymer, etc.

Referring to FIG. 2G, a patterned resist layer 29 is formed on the conductive layer 28. The patterned resist layer 29 can be fabricated by printing, spin-coating, coating or pressing a photoresist layer such as dry-film or liquid photoresist on the conductive layer 28, and then patterning the photoresist layer using exposing and developing processes. As a result, the patterned resist layer 29 covers a portion of the conductive layer 28 and has a plurality of openings 290 defined for electroplating, wherein some of the openings 290 correspond in position to the gold bumps 25. Certainly, the laser drilling or plasma technique can also be employed onto an insulating layer to form the patterned resist layer 29 with a plurality of openings 290.

Referring to FIG. 2H, an electroplating process is performed. The conductive layer 28 is used as the current conducting path to form a circuit structure 30 in the openings 290 by electroplating and allow the circuit structure 30 to be electrically connected to the gold bumps 25.

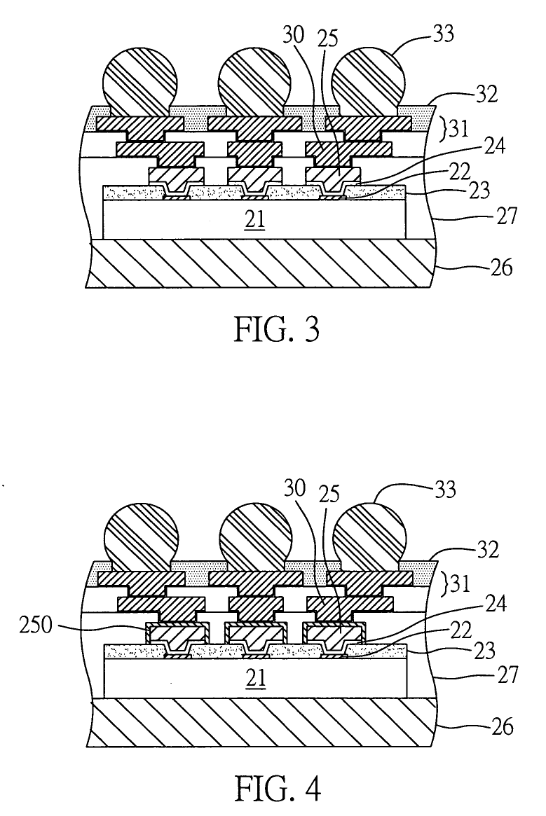

Referring to FIG. 2I, the resist layer 29 and the portion of the conductive layer 28 covered by the resist layer 29 are removed by for example an etching process, etc. Further, as shown in FIG. 3, a build-up process can be performed to form a build-up circuit structure 31 on the circuit structure 30. A patterned solder mask layer 21 is applied on the build-up circuit structure 31, and a plurality of solder balls 33 (such as tin balls) are formed on the build-up circuit structure 31 to be subsequently electrically connected to other circuit boards or electronic elements. Alternatively, the semiconductor electrical connection structure shown in FIG. 4 has a roughened metal layer 250 formed on each of the gold bumps 25 before fabricating the circuit structure 30, and after the build-up circuit structure 31 and the patterned solder mask layer 32 are formed on the circuit structure 30, the solder balls 33 are implanted on the build-up circuit structure 31 to be subsequently electrically connected to other circuit boards or electronic elements.

As shown in FIG. 2I, the semiconductor electrical connection structure fabricated by the foregoing method according to the present invention comprises: a carrier 26; at least one semiconductor chip 21 mounted on the carrier 26, wherein an active surface of the semiconductor chip 21 has a plurality of electrical connection pads 22 thereon, and a plurality of gold bumps 25 are formed on the electrical connection pads 22 respectively; a dielectric layer 27 formed on the carrier 26 mounted with the chip 21, and having a plurality of openings 270 for exposing the gold bumps 25; and at least one circuit structure 30 formed on the dielectric layer 27 and electrically connected to the gold bumps 25. A protection layer 23 is further formed on the active surface of the chip 21 and has a plurality of openings 230 for exposing the electrical connection pads 22. The gold bumps 25 can be formed on the electrical connection pads 22 via a UBM layer 24. Thus, the electrical connection pads 22 of the chip 21 can be electrically connected to an external device (not shown) via the UBM layer 24, the gold bumps 25 and the circuit structure 30. The semiconductor electrical connection structure can further comprise a build-up circuit structure 31 and a plurality of solder balls 33 (as shown in FIGS. 3 and 4), which are formed on the circuit structure 30.

The present invention integrates a semiconductor chip having gold bumps on a carrier, such that the assembling density and functions of the semiconductor electrical connection structure can be increased, thereby solving the problems in the prior art of being difficult to improve the packaging density and causing an environmental issue in terms of the materials being used. Moreover, the present invention does not need to form presolder bumps on a carrier and preform metal bumps on a semiconductor chip, and does not require the packaging processes. This thus simplifies the fabricating processes and reduces the cost.

Furthermore, in the present invention, a circuit structure is directly built on and electrically connected to the gold bumps of the semiconductor chip, thereby providing good electrical connection and reliability as well as structural simplification. In addition, a roughened metal layer such as copper can be formed on a surface of each of the gold bumps so as to improve bondability between the gold bumps and the dielectric layer.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method of fabricating a semiconductor electrical connection structure, comprising the steps of:
providing a wafer comprising a plurality of semiconductor chips, wherein a plurality of electrical connection pads are provided on an active surface of each of the chips;
forming gold bumps on the electrical connecting pads;
dividing the wafer into the plurality of individual chips each having the gold bumps thereon;
mounting at least one of the chips on a carrier via a non-active surface of the chip;
forming a dielectric layer on the carrier mounted with the chip, and forming a plurality of openings in the dielectric layer to expose the gold bumps of the chip via some of the openings; and
forming a circuit structure on the dielectric layer and in the openings, and allowing the circuit structure to be electrically connected to the gold bumps of the chip.

2. The method of claim 1, wherein the openings of the dielectric layer are formed by a laser drilling, photo imaging or plasma etching technique to expose top surfaces of the gold bumps of the chip.

3. The method of claim 1, wherein the circuit structure is fabricated by the steps of:
forming a conductive layer on the dielectric layer and in the openings;
applying a resist layer on the conductive layer and patterning the resist layer, such that the resist layer is formed with a plurality of openings defined for electroplating;
electroplating the circuit structure in the openings of the resist layer; and
removing the resist layer and the conductive layer covered by the resist layer.

4. The method of claim 1, further comprising a step of performing a build-up process to form a build-up circuit structure on the circuit structure.

5. The method of claim 4, further comprising a step of applying a solder mask layer on the build-up circuit structure, the solder mask layer having a plurality of openings for exposing a portion of the build-up circuit structure.

6. The method of claim 5, further comprising a step of forming solder balls in the openings of the solder mask layer.

7. The method of claim 1, wherein the carrier is a metal plate, insulating plate or circuit board.

8. The method of claim 1, wherein the chip is mounted on a surface, in a recess or on a protrusion of the carrier.

9. The method of claim 1, wherein the gold bumps are formed by a technique selected from the group consisting of physical deposition, chemical deposition, sputtering, evaporation, electroless plating and electroplating.

10. The method of claim 1, wherein an under bump metallurgy layer is formed between the gold bumps and the electrical connecting pads.

11. The method of claim 1, wherein a metal layer is formed on a surface of each of the gold bumps and roughened to increase bondability between the gold bumps and the insulating layer.

12. A semiconductor electrical connection structure comprising:
a carrier;
at least one semiconductor chip mounted on the carrier, wherein a plurality of electrical connection pads are provided on a surface of the chip, and gold bumps are formed on the electrical connection pads;
a dielectric layer formed on the carrier mounted with the chip, and having a plurality of openings for exposing the gold bumps; and
a circuit structure formed on the dielectric layer and electrically connected to the gold bumps.

13. The semiconductor electrical connection structure of claim 12, further comprising an under bump metallurgy layer formed between the gold bumps and the electrical connection pads.

14. The semiconductor electrical connection structure of claim 12, further comprising a build-up circuit structure formed on the circuit structure.

15. The semiconductor electrical connection structure of claim 14, further comprising a solder mask layer applied on the build-up circuit structure, the solder mask layer having a plurality of openings for exposing a portion of the build-up circuit structure.

16. The semiconductor electrical connection structure of claim 15, further comprising a plurality of solder balls formed in the openings of the solder mask layer.

17. The semiconductor electrical connection structure of claim 12, wherein a metal layer is formed on a surface of each of the gold bumps.

18. The semiconductor electrical connection structure of claim 12, wherein the carrier is a metal plate, insulating plate or circuit board.

19. The semiconductor electrical connection structure of claim 12, wherein the chip is mounted on a surface, in a recession or on a protrusion of the carrier.
